(19) United States
(12) Patent Application Publication
(10) Pub. No.: US 2022/0020650 A1
(43) Pub. Date: Jan. 20, 2022

(54) DEFECTIVE CHIP PROCESSING METHOD

(71) Applicant: NVIDIA Corporation, Santa Clara, CA (US)

(72) Inventor: David Greenlaw, Palo Alto, CA (US)

(21) Appl. No.: 16/930,136

(22) Filed: Jul. 15, 2020

(51) Int. Cl. H01L 21/66; H01L 21/268; H01L 21/306; H01L 21/02

(52) U.S. Cl. CPC H01L 22/22; H01L 21/268; H01L 21/0217; H01L 21/02164; H01L 21/30625

(57) ABSTRACT

When a chip, or manufactured integrate circuit, is found to have a portion that is defective, “floorsweeping” may be used to salvage the working portion of the chip. Floorsweeping involves downgrading, or turning off, the portion of the chip with the defect and then operating the remaining portion of the chip as a lower quality chip than the larger chip that was originally intended. In use, applications will then only use the active portion of the chip. However, the resulting lower quality chip will still have the same static leakage of the larger, non-defective chip. This leakage results from a voltage still being applied to the entire area of the larger chip, even though a portion of that area has been downgraded. The present disclosure provides a method for processing defective chips to form a smaller chip that avoids the excess static leakage associated with floorsweeping by physically removing the defective portion of the chip.

### TECHNICAL FIELD

The present disclosure relates to techniques for optimizing the value of defective integrated circuits.

### BACKGROUND

The processes used to build integrated circuits generate defects which will limit the yield of those silicon chips. Much effort is spent by the manufacturer to minimize these defects, but some will always remain. It is desirable to find ways to bring the non-defective portions of defective chips to market, even though their value is reduced by the presence of a defect. This disclosure shows ways to minimize the value reduction of such defective chips in the market.

To date, “floorsweeping” has generally been used as a technique to salvage some value from defective chips. Floorsweeping involves downgrading, or turning off, the portion of the chip with the defect and then operating the remaining portion of the chip as a lower quality chip than the larger chip that was originally intended. In use, applications will then only use the active portion of the chip. However, floorsweeping is still associated with some limitations. For example, the floorswept chip, which will have the same performance of a smaller manufactured chip with no defects, may have the same static leakage of a larger, non-defective chip. This leakage results from a voltage still being applied to the entire area of the larger chip, even though the defective portion of that area has been downgraded and does not contribute to performance. There is a need for addressing these issues and/or other issues associated with the prior art.

### SUMMARY

A method, computer readable medium, and system are disclosed for processing a defective chip. In use, a defective portion of a chip is identified. Additionally, the defective portion of the chip is physically cut away from a working portion of the chip. Further, the cut side of the working portion of the chip is processed to ensure integrity over the operating life of the chip.

### BRIEF DESCRIPTION OF THE DRAWINGS

FIG. 1 illustrates a flowchart of a method for processing a defective chip, in accordance with an embodiment.

FIG. 2A illustrates a diagram of a chip having a working portion and a defective portion, in accordance with an embodiment.

FIG. 2B illustrates the chip of FIG. 2A having the defective portion physically cut away from the working portion, in accordance with an embodiment.

FIG. 2C illustrates a reduced size chip resulting after having the cut side of the working portion of the chip from FIG. 2B polished, in accordance with an embodiment.

FIGS. 3A-3B illustrate test structures that could be used to determine the area penalty required to implement the method of FIG. 1.

### DETAILED DESCRIPTION

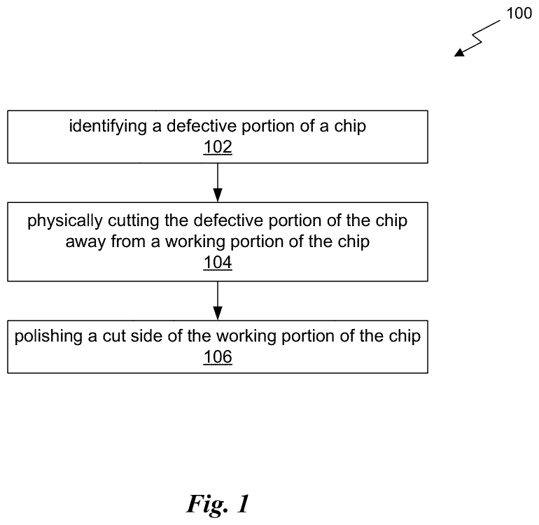

FIG. 1 illustrates a flowchart of a method 100 for processing a defective chip, in accordance with an embodiment. The method 100 involves a physical processing of a larger chip identified as having one or more defects. The method 100 may be performed by a machine or a combination of machines, for example, having cutting and polishing capabilities as described below.

The chip may be a graphics processing unit (GPU), for example having a graphics processing cluster. Of course, however, the chip may be any other integrated circuit which may have repeating sub-blocks.

In step 102, a defective portion of the chip is identified. The defective portion of the chip may include one or more neighboring sub-blocks of the repeating sub-blocks, in one embodiment. For example, the defective portion may include a contiguous portion of the chip (i.e. contiguous sub-blocks) in which one or more defects have been identified. Thus, the defective portion may be a select area of the chip that encompasses one or more defects.

The defective portion of the chip may be identified from results of testing of the chip. For example, the chip may be probed at a wafer level to find the defects on the chip, and then a portion of the chip encompassing those defects may be identified. Each defect on the chip may typically prevent the chip from operating as intended.

Additionally, in step 104, the defective portion of the chip is physically cut away from a working portion of the chip. The working portion of the chip may be a portion of the chip other than the defective portion of the chip. Thus, the working portion of the chip may operate as intended.

In one embodiment, physically cutting the defective portion of the chip away from the working portion of the chip includes making a laser cut through the chip to cut the defective portion of the chip away from the working portion of the chip. Depending on the location of the defective portion of the chip relative to the working portion of the chip, the laser cut may be made vertically or horizontally through the chip. Of course, multiple laser cuts (i.e. vertical and/or horizontal) may be made in this manner to physically cut the defective portion of the chip away from the working portion of the chip. In another embodiment, the physical cutting may include sawing the defective portion of the chip away from the working portion of the chip.

In another embodiment, the laser cut may be made in a lane existing between the defective portion of the chip and the remaining portion of the chip. The lane may be a gap of a particular width existing between two rows or two columns of repeating sub-blocks of the chip. The lane may be manufactured during manufacturing of the chip. In yet another embodiment, the laser cut may be made in the defective portion of the chip.

Prior to the physical cutting, the defective portion of the chip and the remaining portion of the chip may be connected via wires extending across the lane. For example, sub-blocks on either side of the lane may be connected via the wires. In one embodiment, the lane may be an contain internal scribe seals with openings through which the wires extend between the defective portion of the chip and the working portion of the chip.

It should be noted that the physical cutting may be performed such that the wires, when cut, are isolated from each other. In other words, the physical cutting, which cuts through the above mentioned wires in one embodiment, may ensure that cut ends of the wires on the working portion of the chip are isolated from each other (e.g. are not in contact with one another which could cause a short circuit the working portion of the chip).

As another option, the physical cutting may be performed such that other wires within the remaining portion of the chip which do not connect to the defective portion of the chip (i.e. which do not extend across the lane) are kept intact (i.e. are not accidentally cut). It may be ensured that these wires are kept intact by making the physical cut within the lane.

Further, in step 106, the cut side of the working portion of the chip is polished. The polishing may be performed by applying a chemical mechanical polishing (CMP) to the cut side of the working portion of the chip. The polishing may be used to recess any cut wires exposed at the surface of the cut side of the working portion of the chip. When the cut is made through the defective portion of the chip, the polishing may also bring the cut side of the working portion of the chip into the lane existing between the defective portion of the chip and the working portion of the chip.

As an option, a sealant may also be applied to the polished cut side of the working portion of the chip. The sealant may “seal” any cut wires exposed at the polished surface of the cut side of the working portion of the chip. In one embodiment, the sealant may be a passivation layer. Such passivation layer may optionally be a silicon oxide/silicon nitride stack.

To this end, the method 100 may be used to salvage the working part of the chip in a manner that is different from traditional floorsweeping of defective chips. The method 100, as described above, processes the defective chip by physically removing the defective portion of the chip from the working portion of the chip. The smaller chip resulting from this processing will operate at a reduced performance than the original chip (were the original chip not defective), but will also operate with a reduced static leakage than the original chip due to the reduced physical size of the smaller chip with respect to the original chip.

As a result of the method 100, a reduced size chip may be provided, which includes specifically a working portion of a larger chip. The working portion of the larger chip has a cut side from which a defective portion of the larger chip was physically cut away. The cut side of the working portion of the larger chip is also polished, as described above.

The reduced size chip may operate as a GPU, in one embodiment. In another embodiment, the working portion of the larger chip may include one or more neighboring sub-blocks of a plurality of repeating sub-blocks of the larger chip. As an option, the reduced size chip may also include a sealant applied to the polished cut side of the working portion of the larger chip, where the sealant may be a passivation layer.

More illustrative information will now be set forth regarding various optional architectures and features with which the foregoing framework may be implemented, per the desires of the user. It should be strongly noted that the following information is set forth for illustrative purposes and should not be construed as limiting in any manner. Any of the following features may be optionally incorporated with or without the exclusion of other features described.

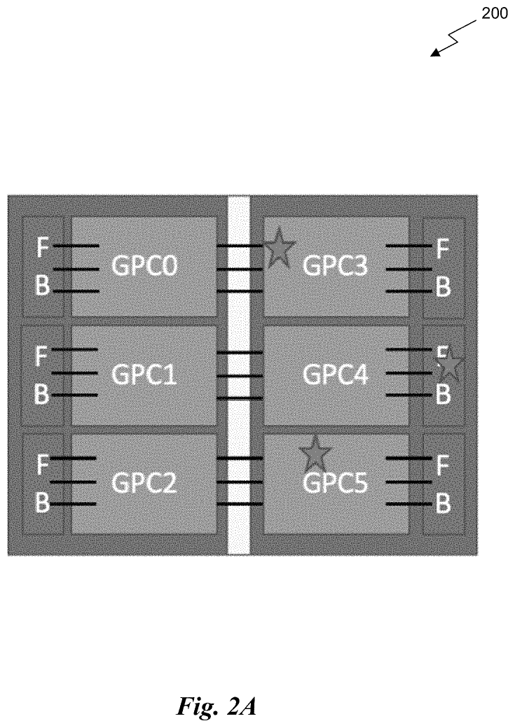

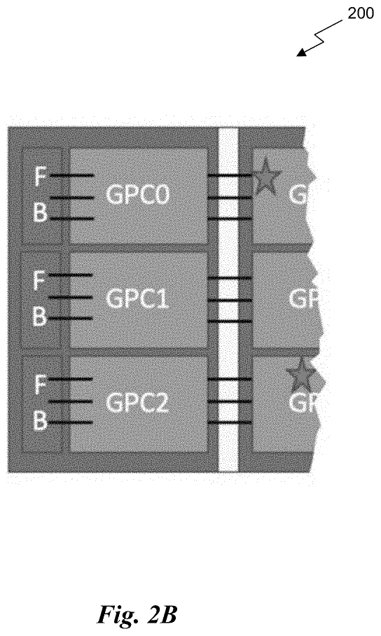

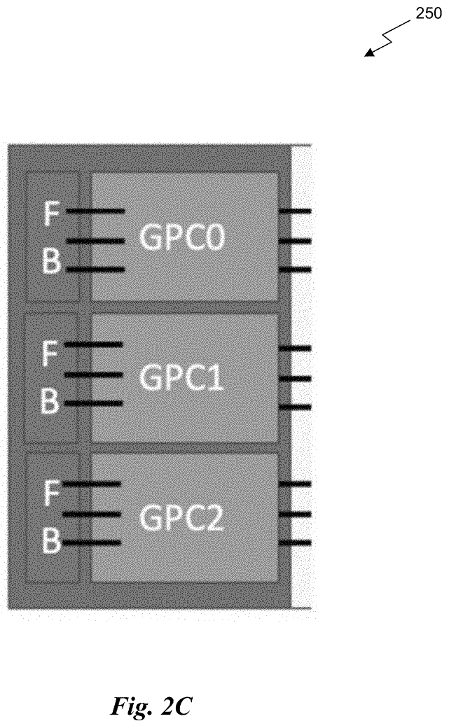

FIG. 2A illustrates a diagram of a chip 200 having a working portion and a defective portion, in accordance with an embodiment. The chip 200 may be the defective chip described above with respect to FIG. 1. In the present embodiment, the chip 200 is a GPU. However, the descriptions below may equally apply to other types of chips.

As shown, the chip 200 includes a plurality of sub-blocks GPC0-GPC5 arranged in rows and columns. Each sub-block GPC0-GPC5 is a circuit capable of operating independently. However, the original chip 200 is designed such the sub-blocks GPC0-GPC5 operate in combination with one another (e.g. in parallel) to increase performance of the chip 200.

A lane (gap) exists between each of the rows and each of the columns. Each lane is of a particular width as defined by a design of the chip 200 and manufactures as part of the chip 200 during the manufacturing of the chip 200. Each lane may be ˜50 um in width stretching across the full height or width of the chip 200.

The sub-blocks GPC0-GPC5 are interconnected via metal wires, as shown. In each lane, only metal connections between sub-blocks GPC0-GPC5 may be routed, along with simple “repeater” transistors if needed. Thus, sub-blocks GPC0-GPC5 exist fully on one side or the other of a lane.

As also shown, the chip 200 includes a plurality of defects in a portion of the sub-blocks GPC0-GPC5, as indicated by the stars. The defects in this example are located in the sub-blocks GPC3-GPC5 of the right column of the chip 200. Thus, the defective portion of the chip 200 may be identified as the right column of the chip 200. It should be noted that the defects may be caused by errors in the design of the chip 200 and/or errors in the manufacturing of the chip 200. The defective chip 200 may be processed as described further below in FIGS. 2B-C.

FIG. 2B illustrates the chip 200 of FIG. 2A having the defective portion physically cut away from the working portion, in accordance with an embodiment.

Once the defective portion of the chip is identified, the defective portion is physically cut away from the remaining (i.e.) working portion of the chip. In particular, the chip 200 is sawn or laser cut to remove the largest portion of the unwanted, defective silicon. Immediately after this operation, the chip 200 edge will be ragged and contain much stray conducting material.

In the embodiment shown, the cut is made through the sub-blocks included in the defective portion of the chip 200. In another embodiment, however, the cut may be made through the vertical lane existing between the left column of sub-blocks and the right column of sub-blocks. However, the cut is made some particular distance from the working portion of the chip 200 to avoid cracking the working portion of the chip 200.

Due to the ragged nature of the cut side of the working portion of the chip 200, the cut side of the working portion of the chip 200 is polished. Where the cut is made through the sub-blocks included in the defective portion of the chip 200, a CMP step may be used to bring the cut edge into the lane described above. In any case, the polishing will result in a much smoother silicon edge than the ragged edge resulting from the physical cut. The chemical component of this CMP step may contain chemistry that is a mild etchant of Cu/Ti/Ta/Co in order to recess the interconnect metal at the surface of the cut edge.

FIG. 2C illustrates a reduced size chip 250 resulting after having the cut side of the working portion of the chip from FIG. 2B polished, in accordance with an embodiment. In the embodiment shown, the polished cut side is formed in the vertical lane originally existing between the left and right columns of sub-blocks.

In an embodiment (not shown), a passivation layer may be applied to the polished edge. This might be a Silicon Oxide/Silicon Nitride stack, or could be some other material more applied to just the polished silicon edge.

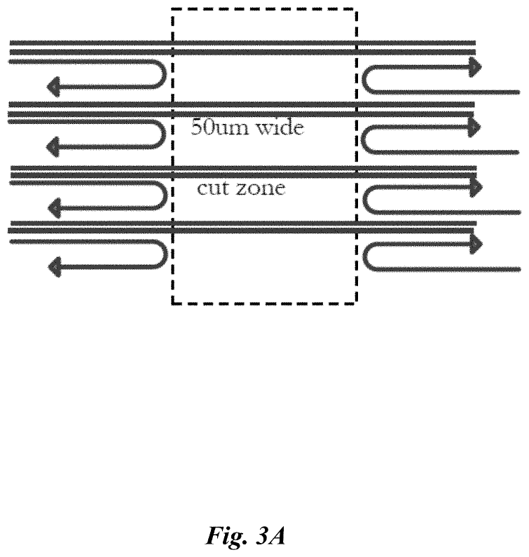

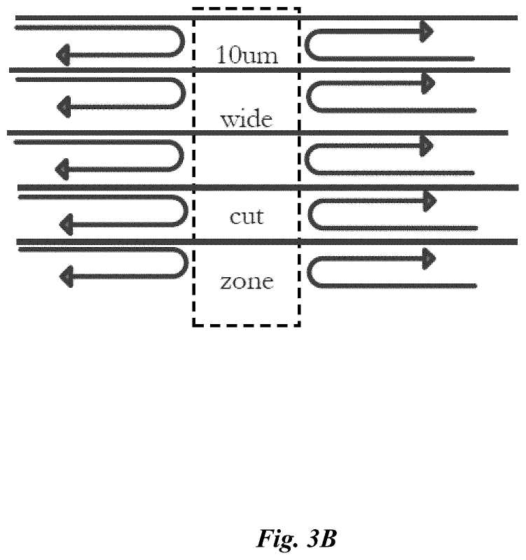

FIGS. 3A-B illustrate test structures that could be used to determine the area penalty (i.e. minimum width) required to implement the method of FIG. 1. In particular, the lane must be wide enough to ensure that the processing of the cut and polished edge does not touch the circuitry in the good portion of the chip. However, if this lane is made too wide, then it may not make economic sense to implement this scheme because the area penalty for all chips made with this maskset, including the non-defective ones, would be too costly.

FIG. 3A illustrates a test chip with a 50 um wide lane, in accordance with an embodiment. FIG. 3B illustrates a test chip with a 10 um wide lane, in accordance with another embodiment.

The lines shown in FIGS. 3A-B are wires within each sub-block and interconnecting sub-blocks across the lane. While the larger lane of FIG. 3A may prove to better help insulate the working portion of the chip from cracks during the cutting, by providing a larger buffer between the location of the cut and the working portion of the chip, this larger lane comes at the cost of a larger chip.

On the other hand, while the smaller lane of FIG. 3B would reduce the size of the chip from the size required with the design in FIG. 3A, this smaller lane may make prove to increase the possibility of the working portion of the chip cracking during the cutting, due to the decreased gap between the location of the cut and the working portion of the chip. Based on test processing applied to the test chips, a minim required width of the lane may be determined. The chip may then be designed with a lane having the minimum required (or greater) width which balances the size of the resulting chip with the desire to eliminate the possibility of cracking when physically removing the defective portion of the chip from the working portion of the chip.

1. A method, comprising:
identifying a defective portion of a chip;
physically cutting the defective portion of the chip away from a working portion of the chip;
polishing a cut side of the working portion of the chip.

2. The method of claim 1, wherein the chip is a graphics processing unit (GPU).

3. The method of claim 1, wherein the chip includes repeating sub-blocks.

4. The method of claim 3, wherein the defective portion of the chip includes one or more neighboring sub-blocks of the repeating sub-blocks.

5. The method of claim 1, wherein the defective portion of the chip is identified from results of testing of the chip.

6. The method of claim 1, wherein physically cutting the defective portion of the chip away from the working portion of the chip includes making at least one of a vertical laser cut or a horizontal laser cut through the chip.

7. The method of claim 6, wherein the at least one of the vertical laser cut or the horizontal laser cut is made in a lane existing between the defective portion of the chip and the working portion of the chip.

8. The method of claim 7, wherein, prior to the physical cutting, the defective portion of the chip and the working portion of the chip are connected via wires extending across the lane.

9. The method of claim 6, wherein the at least one of the vertical laser cut or the horizontal laser cut is made in the defective portion of the chip.

10. The method of claim 9, wherein the polishing brings the cut side of the working portion of the chip into a lane existing between the defective portion of the chip and the working portion of the chip.

11. The method of claim 1, wherein the physical cutting ensures that wires within the working portion of the chip, which do not connect to the defective portion of the chip, are kept intact.

12. The method of claim 1, wherein polishing the cut side of the working portion of the chip includes applying a chemical mechanical polishing (CMP) to the cut side of the working portion of the chip.

13. The method of claim 1, further comprising:
applying a sealant to the polished cut side of the working portion of the chip.

14. The method of claim 13, wherein the sealant is a passivation layer.

15. The method of claim 14, wherein the passivation layer is a silicon oxide/silicon nitride stack.

16.-20. (canceled)
